(19) United States
(12) Patent Application Publication
(10) Pub. No.: US 2026/0171785 A1
(43) Pub. Date: Jun. 18, 2026

(54) ADAPTIVE BATTERY CELL MONITORING DEVICE EQUIPPED WITH AN ELECTRICAL OVERSTRESS (EOS) PROTECTION CIRCUIT

(71) Applicants: HYUNDAI MOTOR COMPANY, Seoul (KR); KIA CORPORATION, Seoul (KR)

(72) Inventor: Woocheol Shin, Hwaseong-si (KR)

(73) Assignees: HYUNDAI MOTOR COMPANY, Seoul (KR); KIA CORPORATION, Seoul (KR)

(21) Appl. No.: 19/230,338

(22) Filed: Jun. 6, 2025

(30) Foreign Application Priority Data
Dec. 17, 2024 (KR) 10-2024-0188521

(51) Int. Cl. H02H 7/18; G01R 31/3835; G01R 31/396; H01M 10/42; H01M 50/574; H02H 9/00

(52) U.S. Cl. CPC H02H 7/18; G01R 31/3835; G01R 31/396; H01M 50/574; H02H 9/005; H01M 10/425; H01M 2010/4271

(57) ABSTRACT

An adaptive battery cell monitoring device includes a cell monitoring circuit configured to monitor n battery cells (where n is a natural number) included in a battery module. The device further includes an electrical overstress (EOS) protection circuit configured to protect the cell monitoring circuit from external EOS. The EOS protection circuit is connected between an uppermost terminal of the cell monitoring circuit and a ground terminal of the cell monitoring circuit. The uppermost terminal of the cell monitoring circuit is connected to a positive electrode of an uppermost battery cell of the battery module including k battery cells (where k is a natural number equal to or less than n). The ground terminal of the cell monitoring circuit is connected to a negative electrode of a bottommost battery cell of the battery module. The device further includes a first bypass circuit configured to bypass the external EOS.

### CROSS-REFERENCE TO RELATED APPLICATION

This present application claims the benefit of and priority to Korean Patent Application No. 10-2024-0188521, filed on Dec. 17, 2024, in the Korean Intellectual Property Office, the entire contents of which are incorporated herein by reference.

### TECHNICAL FIELD

The present disclosure relates to a battery cell monitoring device equipped with an electrical overstress (EOS) protection circuit. More particularly, the present disclosure relates to an adaptive battery cell monitoring device equipped with an EOS protection circuit for protecting the battery cell monitoring device from external EOS.

### BACKGROUND

As customer demand for electric vehicles increases, not only the battery systems of electric vehicles but also the systems of high-voltage electrical components, such as motors and inverters, are becoming increasingly complex.

Electric vehicles comprise complex systems, which, unlike other electric devices, are installed in confined spaces (e.g., a common ground (GND)) and exposed to harsh conditions (e.g., vibration and high power). As a result, unexpected electrical noise, e.g., electrical overstress (EOS), occurs frequently.

Therefore, the battery system, which serves as the energy source for the high-voltage system of electric vehicles, must withstand the electrical noise generated by these high-voltage electrical components.

The battery cell monitoring device is directly connected to a plurality of battery cells of the high-voltage battery and performs the role of monitoring the battery cells. For the battery cell monitoring device to monitor the battery cells properly, the battery cell monitoring device must not be damaged by the high-voltage electrical noise introduced to the battery cells. To address this, most battery cell monitoring devices are equipped with an EOS protection circuit to prevent high-voltage electrical noise.

However, in the case of the EOS protection circuit based on existing technology, when an uppermost fuse or a bottommost fuse among the sensing line fuses of the battery module is blown, the EOS protection circuit of the battery cell monitoring device cannot operate normally.

Accordingly, when the external EOS occurs, the battery cell monitoring device based on existing technology has a significant drawback of being highly vulnerable to the EOS. As a result, the battery cell monitoring device may be damaged, and thus serious issues may be caused, such as battery cell overheating or fire. The external EOS may be generated, for example, by high-voltage electrical components, such as motors and inverters, busbar vibrations, or relay on/off operations. The subject matter described in this background section is intended to promote an understanding of the background of the disclosure and thus may include subject matter that is not already known to those of ordinary skill in the art. The statements in this section merely provide background information related to the present disclosure and may not constitute prior art.

### SUMMARY

The present disclosure provides an adaptive battery cell monitoring device equipped with an electrical overstress (EOS) protection circuit that operates normally even when an uppermost fuse and/or a bottommost fuse among sensing line fuses of a battery module is/are blown.

In addition, the present disclosure provides an adaptive battery cell monitoring device equipped with an EOS protection circuit that includes a bypass circuit to bypass EOS introduced from the battery module to the EOS protection circuit and thus protects the battery cell monitoring device.

Further, the present disclosure is directed to providing an adaptive battery cell monitoring device equipped with an EOS protection circuit, which can be used adaptively regardless of the number of battery cells included in a battery module.

The present disclosure is not limited to that mentioned above, and other aspects and advantages not mentioned above should be understood from the present disclosure and become more apparent from the embodiments. Moreover, aspects of the present disclosure may be realized by the means and combinations thereof indicated in claims.

An aspect of the present disclosure provides an adaptive battery cell monitoring device. The device includes a cell monitoring circuit configured to monitor n battery cells (where n is a natural number) included in a battery module. The device further includes an electrical overstress (EOS) protection circuit configured to protect the cell monitoring circuit from external EOS. The EOS protection circuit is connected between an uppermost terminal of the cell monitoring circuit and a ground terminal of the cell monitoring circuit. The uppermost terminal of the cell monitoring circuit is connected to a positive electrode of an uppermost battery cell of the battery module including k battery cells (where k is a natural number equal to or less than n). The ground terminal of the cell monitoring circuit is connected to a negative electrode of a bottommost battery cell of the battery module. The device further includes a first bypass circuit configured to bypass the external EOS. The first bypass circuit is connected between a positive electrode of a next-uppermost battery cell of the battery module and the uppermost terminal of the cell monitoring circuit.

The first bypass circuit may include a first diode connected between a positive electrode of the next-uppermost battery cell of the battery module and the uppermost terminal of the cell monitoring circuit.

The first bypass circuit may further include a second diode connected between the positive electrode of the uppermost battery cell of the battery module and the uppermost terminal of the cell monitoring circuit.

The battery cell monitoring device may further include a second bypass circuit configured to bypass the external EOS and connected between the ground terminal of the cell monitoring circuit and a positive electrode of the bottommost battery cell of the battery module.

The second bypass circuit may include a third diode and a resistor. A first end of the third diode is connected to the ground terminal of the cell monitoring circuit. A second end of the third diode is connected to a first end of the resistor. A second end of the resistor is connected to a positive electrode of the bottommost battery cell of the battery module.

The resistor may be detachably provided in the second bypass circuit to allow for position adjustment.

An another aspect of the present disclosure provides an adaptive battery cell monitoring device. The device includes a cell monitoring circuit configured to monitor n battery cells (where n is a natural number) included in a battery module. The device further includes an electrical overstress (EOS) protection circuit configured to protect the cell monitoring circuit from external EOS. The EOS protection circuit is connected between an uppermost terminal of the cell monitoring circuit and a ground terminal of the cell monitoring circuit. the uppermost terminal of the cell monitoring circuit is connected to a positive electrode of an uppermost battery cell of the battery module including k battery cells (where k is a natural number equal to or less than n), and wherein the ground terminal of the cell monitoring circuit. The ground terminal of the cell monitoring circuit is connected to a negative electrode of a bottommost battery cell of the battery module. The device further includes a bypass circuit configured to bypass the external EOS. The bypass circuit is connected between the ground terminal of the cell monitoring circuit and a positive electrode of the bottommost battery cell of the battery module.

The bypass circuit may include a diode and a resistor. A first end of the diode is connected to the ground terminal of the cell monitoring circuit. A second end of the diode is connected to a first end of the resistor. A second end of the resistor is connected to the positive electrode of the bottommost battery cell of the battery module.

The resistor may be detachably provided in the bypass circuit to allow for position adjustment.

According to the present disclosure, even when the uppermost fuse and/or the bottommost fuse among the sensing line fuses of the battery module are blown, the EOS protection circuit operates normally and thus protects the battery cell monitoring device from external EOS.

As a result, it is possible to prevent the battery cell monitoring device from burning and breaking down and enable the prevention of battery cell overheating or fire in advance.

In addition, according to the present disclosure, the resistor included in the bypass circuit connected to the EOS protection circuit is detachably provided to allow for position adjustment, enabling the EOS protection circuit and the battery cell monitoring device to be used adaptively regardless of the number of battery cells included in the battery module.

### BRIEF DESCRIPTION OF THE DRAWINGS

The foregoing and other aspects, features, and advantages, as well as the following detailed description of the embodiments, should be better understood when read in conjunction with the accompanying drawings. However, the present disclosure is not intended to be limited to the details shown in the drawings, and various modifications and structural changes may be made therein without departing from the spirit of the present disclosure and within the scope and range of equivalents of the claims. Like reference numbers and designations in the various drawings indicate like elements.

FIG. 1 is a schematic diagram showing a battery cell monitoring device equipped with an existing electrical overstress (EOS) protection circuit.

FIG. 2 is a diagram illustrating the effect of EOS on a battery cell monitoring device equipped with an existing EOS protection circuit when the uppermost fuse is blown.

FIG. 3 is a diagram illustrating the effect of EOS on a battery cell monitoring device equipped with an existing EOS protection circuit when the bottommost fuse is blown.

FIG. 4 is a schematic diagram showing a battery cell monitoring device equipped with an EOS protection circuit according to one embodiment of the present disclosure.

FIG. 5 is a diagram illustrating the effect of EOS on a battery cell monitoring device equipped with an EOS protection circuit when the uppermost fuse is blown according to one embodiment of the present disclosure.

FIG. 6 is a diagram illustrating the effect of EOS on a battery cell monitoring device equipped with an EOS protection circuit when the bottommost fuse is blown according to one embodiment of the present disclosure.

FIG. 7 is a schematic diagram showing an adaptive battery cell monitoring device equipped with an EOS protection circuit according to one embodiment of the present disclosure.

FIG. 8 is a diagram illustrating an adaptive battery cell monitoring device equipped with an EOS protection circuit and illustrating a state in which a battery module including 16 battery cells is connected to the adaptive battery cell monitoring device, which is capable of monitoring up to 16 battery cells, according to one embodiment of the present disclosure.

FIG. 9 is a diagram illustrating an adaptive battery cell monitoring device equipped with an EOS protection circuit and illustrating a state in which a battery module including 9 battery cells is connected to the adaptive battery cell monitoring device, which is capable of monitoring up to 16 battery cells, according to one embodiment of the present disclosure.

### DETAILED DESCRIPTION

Hereinafter, embodiments disclosed in the present document are described in detail with reference to the accompanying drawings. Like reference numerals designate like elements, and redundant descriptions thereof have been omitted. Further, the terms, such as “module” and a “unit”, for components used in the present disclosure are given for purpose of convenience in preparing the present disclosure and do not have a meaning or a role distinguished from each other in themselves. In addition, in describing an embodiment disclosed in the present document, if it is determined that a detailed description of a related art incorporated herein unnecessarily obscures the gist of the embodiment, the detailed description thereof has been omitted. Furthermore, it should be understood that the appended drawings are intended only to help understand embodiments disclosed in the present disclosure and do not limit the technical principles and scope of the present disclosure. Instead, it should be understood that the appended drawings include all of the modifications, equivalents, or substitutes described by the technical principles and belonging to the technical scope of the present disclosure.

Although the terms, such as first, second, and the like, may be used herein to describe various elements, these elements should not be limited by these terms. These terms are generally only used to distinguish one element from another.

When an element or a layer is referred to as being “on,” “engaged to,” “connected to,” or “coupled to” another element or another layer, it may be directly on, engaged, connected, or coupled to another element or another layer, or intervening elements or layers may be present between the elements or the layers. In contrast, when an element is referred to as being “directly on,” “directly engaged to,” “directly connected to,” or “directly coupled to” another element or another layer, there may be no intervening elements or layers present between the elements or the layers. When a controller, apparatus, module, component, device, element, or the like of the present disclosure is described as having a purpose or performing an operation, function, or the like, the controller, apparatus, module, component, device, element, or the like should be considered herein as being “configured to” meet that purpose or to perform that operation or function. Each controller, apparatus, module, component, device, element, and the like may separately embody or be included with a processor and a memory, such as a non-transitory computer readable media, as part of the apparatus.

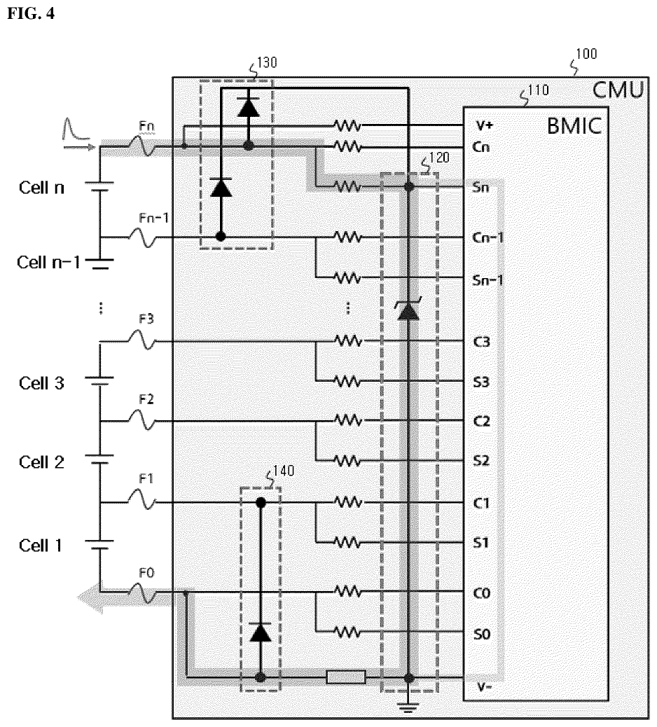

An adaptive battery cell monitoring device equipped with an electrical overstress (EOS) protection circuit according to one embodiment of the present disclosure is described in detail below with reference to FIGS. 4 to 9.

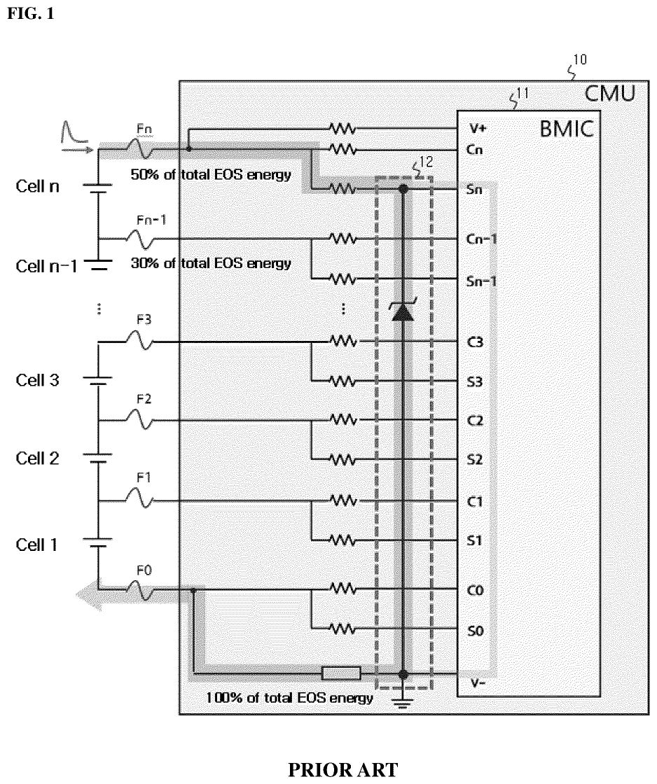

With reference to FIGS. 1, 2, and 3, a battery cell monitoring device equipped with an existing EOS protection circuit is described.

FIG. 1 is a schematic diagram showing a battery cell monitoring device equipped with an existing EOS protection circuit.

Referring to FIG. 1, a battery cell monitoring device 10 according to one embodiment of the present disclosure may include a cell monitoring circuit 11 and an EOS protection circuit 12.

The cell monitoring circuit 11 is a circuit that monitors each of a plurality of battery cells included in a battery module.

For example, the cell monitoring circuit 11 monitors the status of n battery cells Cell 1 to Cell n (where n is a natural number) included in the battery module and performs cell balancing. To achieve this, the cell monitoring circuit 11 is equipped with n+1 voltage sensing terminals C0 to Cn and n+1 cell balancing terminals S0 to Sn.

The n+1 voltage sensing terminals C0 to Cn are connected to positive and negative electrodes of the n battery cells Cell 1 to Cell n through n+1 fuses F0 to Fn to sense the voltage of the n battery cells.

Similarly, the n+1 cell balancing terminals S0 to Sn are connected to the positive and negative electrodes of the n battery cells Cell 1 to Cell n through the n+1 fuses F0 to Fn to perform cell balancing for the n battery cells.

The EOS protection circuit 12 is a circuit for protecting the cell monitoring circuit 11 from external EOS.

For example, the EOS protection circuit 12 is connected between an uppermost terminal Sn of the cell monitoring circuit 11 and a ground terminal v− of the cell monitoring circuit 11 to protect the cell monitoring circuit 11 from the external EOS. The uppermost terminal Sn is connected to a positive electrode of an uppermost battery cell Cell n of the battery module through an uppermost fuse Fn, and the ground terminal v− is connected to a negative electrode of a bottommost battery cell Cell 1 of the battery module through a bottommost fuse F0.

When the EOS is introduced from the outside, the largest amount of EOS (e.g., approximately 50% of the total EOS energy) flows through the uppermost fuse Fn, which is connected to the positive electrode of the uppermost battery cell Cell n of the battery module. The next largest amount of EOS (e.g., approximately 30% of the total EOS energy) flows through a next-uppermost fuse Fn−1, which is connected to a positive electrode of a next-uppermost battery cell Cell n−1 of the battery module. In this manner, the amount of EOS introduced through each fuse F1 to Fn progressively decreases, and the EOS introduced through the fuses flows into the battery cell monitoring device 100.

When the uppermost fuse Fn and the bottommost fuse F0 are in a normal state, as shown in FIG. 1, most of the introduced EOS passes through the EOS protection circuit 12 and is discharged to the outside. As a result, only a portion of the EOS affects the cell monitoring circuit 11, and thus the cell monitoring circuit 11 is protected.

However, when the uppermost fuse Fn and/or the bottommost fuse F0 is blown, most of the introduced EOS passes through the cell monitoring circuit 11. This causes damages to the cell monitoring circuit 11.

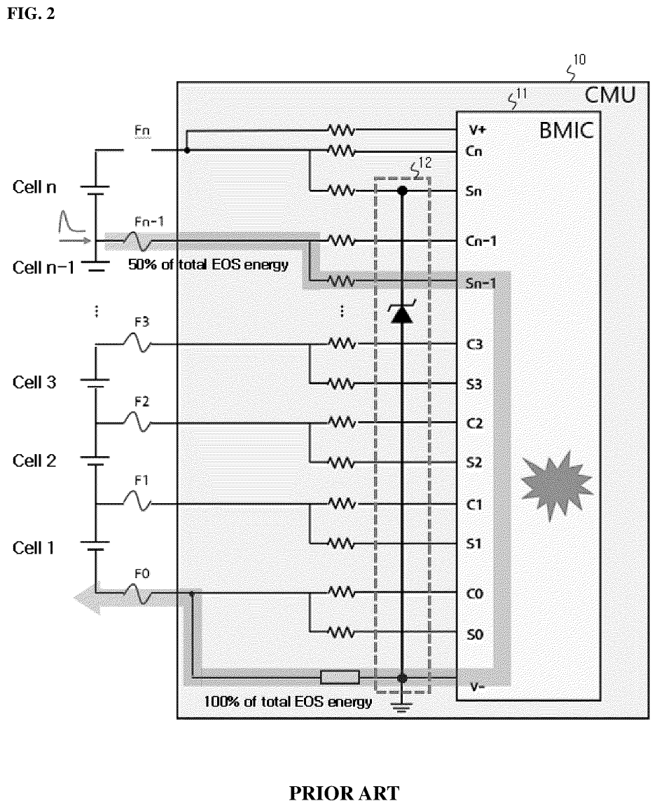

FIG. 2 is a diagram illustrating the effect of EOS on the battery cell monitoring device equipped with the existing EOS protection circuit when the uppermost fuse is blown.

As shown in FIG. 2, when the uppermost fuse Fn connected to the positive electrode of the uppermost battery cell Cell n of the battery module is blown, most of the introduced EOS flows into the cell monitoring circuit 11 through the next-uppermost fuse Fn−1, which is connected to the positive electrode of the next-uppermost battery cell Cell n−1 of the battery module. However, because the EOS protection circuit 12 is connected to the uppermost terminal Sn of the cell monitoring circuit 11, which is connected to the blown uppermost fuse Fn, most of the EOS bypasses the EOS protection circuit 12 and directly passes through the cell monitoring circuit 11. This causes damages to the cell monitoring circuit 11.

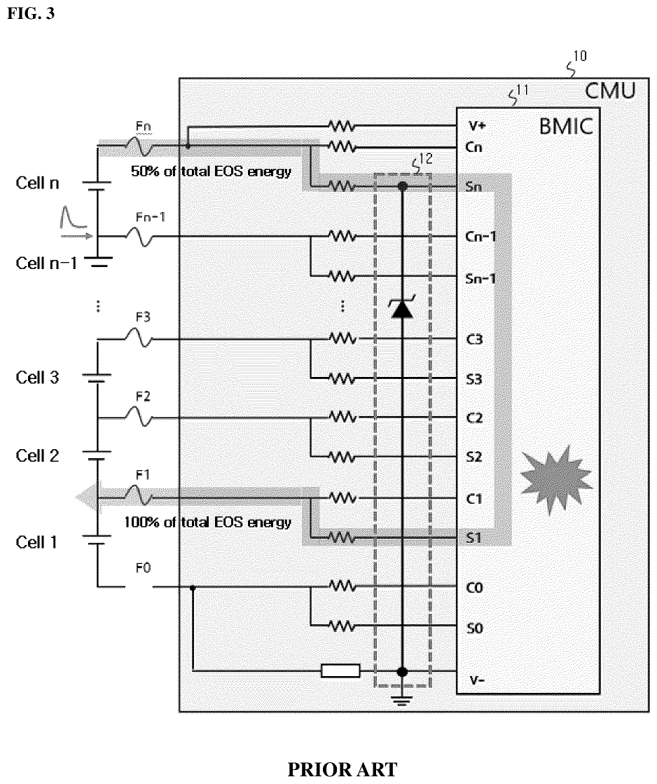

FIG. 3 is a diagram illustrating the effect of EOS on the battery cell monitoring device equipped with the existing EOS protection circuit when the bottommost fuse is blown.

As shown in FIG. 3, when the bottommost fuse F0 connected to the negative electrode of the bottommost battery cell Cell 1 of the battery module is blown, most of the introduced EOS flows into the cell monitoring circuit 11 through the uppermost fuse Fn, which is connected to the positive electrode of the uppermost battery cell Cell n of the battery module. However, because the EOS protection circuit 12 is connected to the ground terminal v− of the cell monitoring circuit 11, which is connected to the blown bottommost fuse F0, most of the EOS bypasses the EOS protection circuit 12 and directly passes through the cell monitoring circuit 11. This causes damages to the cell monitoring circuit 11.

In the following, a battery cell monitoring device equipped with an EOS protection circuit according to one embodiment of the present disclosure is described in detail with reference to FIGS. 4, 5, and 6.

FIG. 4 is a schematic diagram showing a battery cell monitoring device equipped with an EOS protection circuit according to one embodiment of the present disclosure. The battery cell monitoring device equipped with the EOS protection circuit according to one embodiment of the present disclosure may be implemented as a cell monitoring unit (CMU).

Referring to FIG. 4, a battery cell monitoring device 100 according to one embodiment of the present disclosure may include a cell monitoring circuit 110, an EOS protection circuit 120, a first bypass circuit 130, and a second bypass circuit 140.

The cell monitoring circuit 110 is a circuit that monitors each of a plurality of battery cells included in the battery module. The cell monitoring circuit 110 according to one embodiment of the present disclosure may be implemented as a battery monitoring integrated circuit (BMIC).

The cell monitoring circuit 110 monitors the status of each of n battery cells Cell 1 to Cell n (where n is a natural number) included in the battery module and performs cell balancing. To achieve this, the cell monitoring circuit 110 is equipped with n+1 voltage sensing terminals C0 to Cn and n+1 cell balancing terminals S0 to Sn.

The n+1 voltage sensing terminals C0 to Cn are connected to positive and negative electrodes of the n battery cells Cell 1 to Cell n through n+1 fuses F0 to Fn to sense the voltage of the n battery cells.

Similarly, the n+1 cell balancing terminals S0 to Sn are connected to the positive and negative electrodes of the n battery cells Cell 1 to Cell n through the n+1 fuses F0 to Fn to perform cell balancing for the n battery cells.

The EOS protection circuit 120 is a circuit for protecting the cell monitoring circuit 110 from external EOS. The EOS protection circuit 120 according to one embodiment of the present disclosure may include a transient voltage suppressor (TVS) diode.

For example, the EOS protection circuit 120 is connected between the uppermost terminal Sn of the cell monitoring circuit 110 and a ground terminal v− of the cell monitoring circuit 110 to protect the cell monitoring circuit 110 from the external EOS. The uppermost terminal Sn is connected to the positive electrode of the uppermost battery cell Cell n of the battery module through the uppermost fuse Fn, and the ground terminal v− is connected to the negative electrode of the bottommost battery cell Cell 1 of the battery module through the bottommost fuse F0.

The first bypass circuit 130 is connected between the uppermost terminal Sn of the cell monitoring circuit 110 and a first end of the next-uppermost fuse Fn−1. The first end of the next-uppermost fuse Fn−1 is opposite to a second end of the next-uppermost fuse Fn−1. The second end of the next-uppermost fuse Fn−1 is connected to the positive electrode of the next-uppermost battery cell Cell n−1 of the battery module. The first bypass circuit 130 bypasses the externally introduced EOS, which flows through the next-uppermost fuse Fn−1, to the EOS protection circuit 120.

For example, the first bypass circuit 130 may include a first Schottky diode connected between the uppermost terminal Sn of the cell monitoring circuit 110 and the first end of the next-uppermost fuse Fn−1. The first end of the next-uppermost fuse Fn−1 is opposite to the second end of the next-uppermost fuse Fn−1. The second end of the next-uppermost fuse Fn−1 is connected to the positive electrode of the next-uppermost battery cell Cell n−1 of the battery module. The first bypass circuit 130 bypasses the externally introduced EOS, which flows through the next-uppermost fuse Fn−1, to the EOS protection circuit 120.

Desirably, the first bypass circuit 130 may further include a second Schottky diode connected between the uppermost terminal Sn of the cell monitoring circuit 110 and a first end of the uppermost fuse Fn. The first end of the uppermost fuse Fn is opposite to a second end of the uppermost fuse Fn. The second end of the uppermost fuse Fn is connected to the positive electrode of the uppermost battery cell Cell n of the battery module. The first bypass circuit 130 bypasses the externally introduced EOS, which flows through the uppermost fuse Fn, to the EOS protection circuit 120.

For reference, according to an embodiment of the present disclosure, the uppermost terminal Sn of the cell monitoring circuit 110 is a terminal configured to perform cell balancing for the uppermost battery cell Cell n of the battery module.

In addition, the second bypass circuit 140 is connected between the ground terminal v− of the cell monitoring circuit 110 and a first end of the next-bottommost fuse F1. The first end of the next-bottommost fuse F1 is opposite to a second end of the next-bottommost fuse F1. The second end of the next-bottommost fuse F1 is connected to the negative electrode of the next-bottommost battery cell Cell 2 (i.e., the positive electrode of the bottommost battery cell Cell 1). When the bottommost fuse F0 is blown, the second bypass circuit 140 bypasses the externally introduced EOS through the next-bottommost fuse F1 for external discharge.

For example, the second bypass circuit 140 may include a third Schottky diode connected between a bead and a first end of the next-bottommost fuse F1. The bead is disposed between the bottommost fuse F0 and the ground terminal v− of the cell monitoring circuit 110. The first end of the next-bottommost fuse F1 is opposite to a second end of the next-bottommost fuse F1. The second end of the next-bottommost fuse F1 is connected to the negative electrode of the next-bottommost battery cell Cell 2 (i.e., the positive electrode of the bottommost battery cell Cell 1). When the bottommost fuse F0 is blown, the second bypass circuit 140 bypasses the externally introduced EOS through the next-bottommost fuse F1 for external discharge.

When the EOS is introduced from the outside, the largest amount of EOS (e.g., approximately 50% of the total EOS energy) flows through the uppermost fuse Fn, which is connected to the positive electrode of the uppermost battery cell Cell n of the battery module. The next largest amount of EOS (e.g., approximately 30% of the total EOS energy) flows through the next-uppermost fuse Fn−1, which is connected to the positive electrode of the next-uppermost battery cell Cell n−1 of the battery module. In this manner, the amount of EOS introduced through each fuse F1 to Fn progressively decreases, and the EOS introduced through the fuses flows into the battery cell monitoring device 100.

When the uppermost fuse Fn and the bottommost fuse F0 are in a normal state, as shown in FIG. 4, most of the introduced EOS passes through the EOS protection circuit 120 and is discharged to the outside. As a result, only a portion of the EOS affects the cell monitoring circuit 110, and thus the cell monitoring circuit 110 is protected.

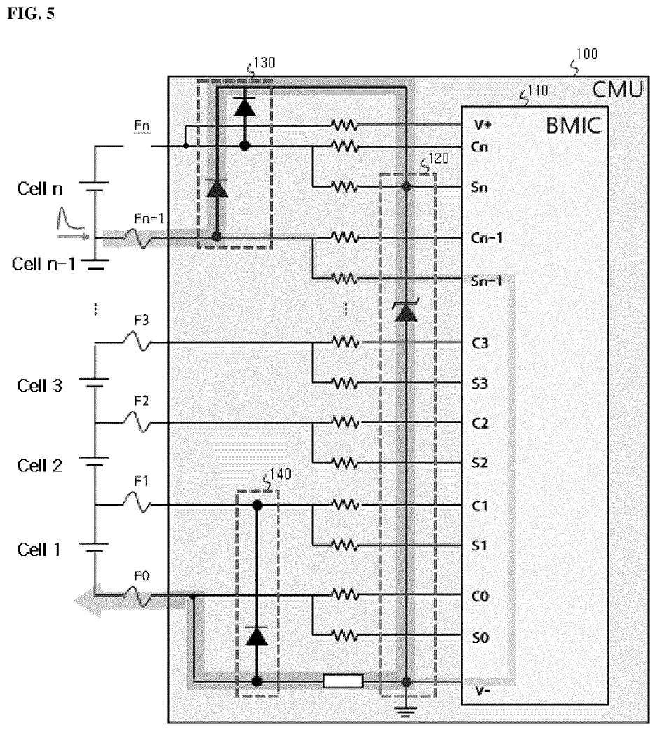

FIG. 5 is a diagram illustrating the effect of EOS on the battery cell monitoring device equipped with the EOS protection circuit according to one embodiment of the present disclosure when the uppermost fuse is blown.

Referring to FIG. 5, when the uppermost fuse Fn connected to the positive electrode of the uppermost battery cell Cell n of the battery module is blown, most of the introduced EOS flows through the next-uppermost fuse Fn−1, which is connected to the positive electrode of the next-uppermost battery cell Cell n−1. The EOS then passes through the first bypass circuit 130 and the EOS protection circuit 120 before being discharged externally. As a result, only a portion of the EOS affects the cell monitoring circuit 110, and thus the cell monitoring circuit 110 is protected.

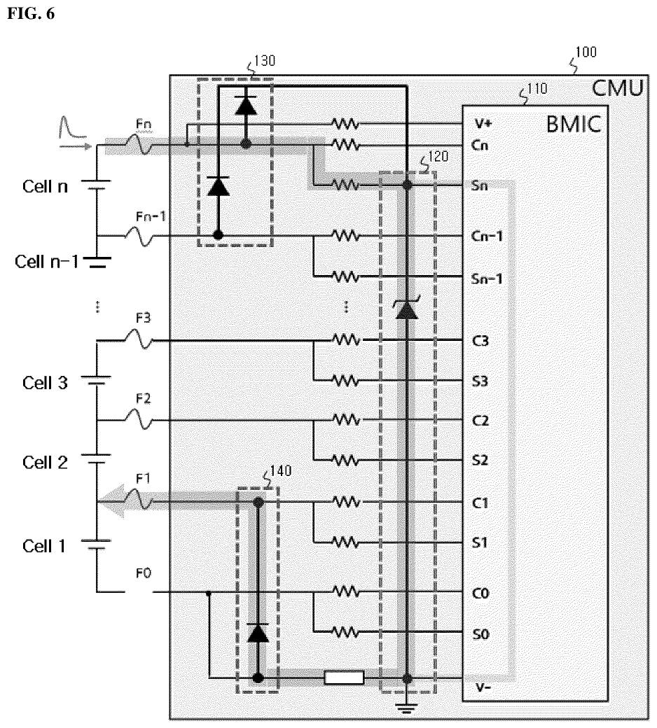

FIG. 6 is a diagram illustrating the effect of EOS on the battery cell monitoring device equipped with the EOS protection circuit according to one embodiment of the present disclosure when the bottommost fuse is blown.

Referring to FIG. 6, when the bottommost fuse F0 connected to the negative electrode of the bottommost battery cell Cell 1 of the battery module is blown, most of the introduced EOS flows through the uppermost fuse Fn, which is connected to the positive electrode of the uppermost battery cell Cell n. The EOS then passes through the EOS protection circuit 120 and the second bypass circuit 140 before being discharged externally. As a result, only a portion of the EOS affects the cell monitoring circuit 110, and thus the cell monitoring circuit 110 is protected.

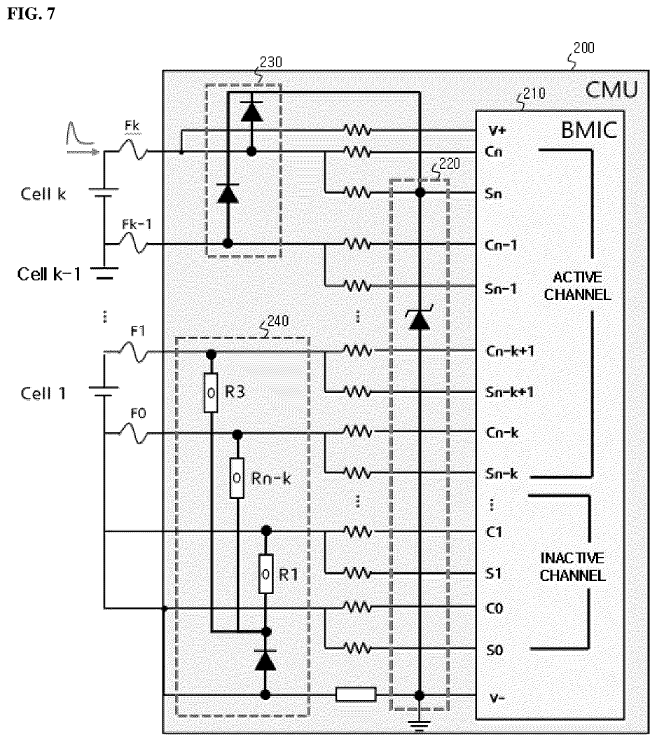

In the following, an adaptive battery cell monitoring device equipped with an EOS protection circuit according to one embodiment of the present disclosure is described in detail with reference to FIGS. 7, 8, and 9.

For reference, the battery cell monitoring device equipped with the EOS protection circuit according to one embodiment of the present disclosure, as described above, is configured such that the battery module including n battery cells is connected to the cell monitoring circuit capable of monitoring up to n battery cells. In contrast, the adaptive battery cell monitoring device equipped with the EOS protection circuit according to another embodiment of the present disclosure, as described below, is configured such that a battery module including k battery cells (k is a natural number equal to or less than n) is connected to the cell monitoring circuit capable of monitoring up to n battery cells.

In other words, the adaptive battery cell monitoring device equipped with the EOS protection circuit according to another embodiment of the present disclosure is a battery cell monitoring device that can be used adaptively regardless of variations in the number of battery cells included in the battery module.

FIG. 7 is a schematic diagram showing an adaptive battery cell monitoring device equipped with an EOS protection circuit according to one embodiment of the present disclosure. The adaptive battery cell monitoring device equipped with the EOS protection circuit according to one embodiment of the present disclosure may be implemented as a cell monitoring unit (CMU).

Referring to FIG. 7, the adaptive battery cell monitoring device 200 according to one embodiment of the present disclosure may include a cell monitoring circuit 210, an EOS protection circuit 220, a first bypass circuit 230, a second bypass circuit 240, and the like.

The cell monitoring circuit 210 is a circuit that monitors each of a plurality of battery cells included in a battery module. The cell monitoring circuit 210 according to one embodiment of the present disclosure may be implemented as a battery monitoring integrated circuit (BMIC).

The cell monitoring circuit 210 monitors the status of each of n battery cells Cell 1 to Cell n (where n is a natural number) included in the battery module and performs cell balancing. To achieve this, the cell monitoring circuit 11 is equipped with n+1 voltage sensing terminals C0 to Cn and n+1 cell balancing terminals S0 to Sn.

When the number of battery cells included in the battery module is k (k is a natural number equal to or less than n), k+1 voltage sensing terminals Cn−k to Cn are connected to the positive and negative electrodes of the k battery cells Cell 1 to Cell k through k+1 fuses F0 to Fk to sense the voltage of the k battery cells.

Similarly, the k+1 cell balancing terminals Sn−k to Sn are connected to the positive and negative electrodes of the k battery cells Cell 1 to Cell k through the k+1 fuses F0 to Fn to perform cell balancing for the k battery cells.

The EOS protection circuit 220 is a circuit for protecting the cell monitoring circuit 210 from external EOS. The EOS protection circuit 120 according to one embodiment of the present disclosure may include a transient voltage suppressor (TVS) diode.

For example, the EOS protection circuit 220 is connected between the uppermost terminal Sn of the cell monitoring circuit 210 and a ground terminal v− of the cell monitoring circuit 210 to protect the cell monitoring circuit 210 from the external EOS. The uppermost terminal Sn is connected to the positive electrode of the uppermost battery cell Cell k of the battery module through the uppermost fuse Fk, and the ground terminal v− is connected to the negative electrode of the bottommost battery cell Cell 1 of the battery module through the bottommost fuse F0.

The first bypass circuit 230 is connected between the uppermost terminal Sn of the cell monitoring circuit 210 and a first end of the next-uppermost fuse Fk−1. The first end of the next-uppermost fuse Fk−1 is opposite to a second end of the next-uppermost fuse Fk−1. The second end of the next-uppermost fuse Fk−1 is connected to the positive electrode of the next-uppermost battery cell Cell k−1 of the battery module. The first bypass circuit 130 bypasses the externally introduced EOS, which flows through the next-uppermost fuse Fk−1, to the EOS protection circuit 220.

For example, the first bypass circuit 230 may include a first Schottky diode connected between the uppermost terminal Sn of the cell monitoring circuit 210 and the first end of the next-uppermost fuse Fk−1. The first end of the next-uppermost fuse Fk−1 is opposite to the second end of the next-uppermost fuse Fk−1. The second end of the next-uppermost fuse Fk−1 is connected to the positive electrode of the next-uppermost battery cell Cell k−1 of the battery module. The first bypass circuit 130 bypasses the externally introduced EOS, which flows through the next-uppermost fuse Fk−1, to the EOS protection circuit 220.

Desirably, the first bypass circuit 230 may further include a second Schottky diode connected between the uppermost terminal Sn of the cell monitoring circuit 210 and a first end of the uppermost fuse Fk. The first end of the uppermost fuse is opposite to a second end of the uppermost fuse Fk. The second end of the uppermost fuse Fk is connected to the positive electrode of the uppermost battery cell Cell k of the battery module. The first bypass circuit 130 bypasses the externally introduced EOS, which flows through the uppermost fuse Fk, to the EOS protection circuit 220.

For reference, according to an embodiment of the present disclosure, the uppermost terminal Sn of the cell monitoring circuit 210 is a terminal configured to perform cell balancing for the uppermost battery cell Cell k of the battery module.

In addition, the second bypass circuit 240 is connected between the ground terminal v− of the cell monitoring circuit 210 and a first end of the next-bottommost fuse F1. The first end of the next-bottommost fuse F1 is opposite to a second end of the next-bottommost fuse F1. The second end of the next-bottommost fuse F1 is connected to the negative electrode of the next-bottommost battery cell (i.e., the positive electrode of the bottommost battery cell Cell 1). When the bottommost fuse F0 is blown, the second bypass circuit 240 bypasses the externally introduced EOS through the next-bottommost fuse F1 for external discharge.

To achieve this, according to an embodiment of the present disclosure, the second bypass circuit 240 may include a third Schottky diode and at least one resistor.

As an example, a first end of the third Schottky diode is connected to a bead, which is connected to the ground terminal v− of the cell monitoring circuit 210. A second end of the third Schottky diode is connected to a first end of a resistor R3. A second end of the resistor R3 is connected to the first end of the next-bottommost fuse F1, while the second end of the next-bottommost fuse F1 is connected to the negative electrode of the next-bottommost battery cell (i.e., the positive electrode of the bottommost battery cell Cell 1). Accordingly, when the bottommost fuse F0 is blown, the EOS is bypassed through the next-bottommost fuse F1 to be discharged externally.

According to an embodiment of the present disclosure, the resistor included in the second bypass circuit 240 is detachably provided to allow for position adjustment and thus enable the EOS protection circuit 220 to be used adaptively regardless of variations in the number of battery cells included in the battery module.

For example, as shown in FIG. 7, the second bypass circuit 240 includes a plurality of resistor (R1, R3, and Rn−k) mounting positions, including a resistor (e.g., R3) installed to connect the second end of the third Schottky diode to each fuse. By mounting the resistor at the appropriate position according to the number of battery cells included in the battery module, the EOS protection circuit 220 and the battery cell monitoring device 200 can be adaptively implemented regardless of the number of battery cells included in the battery module.

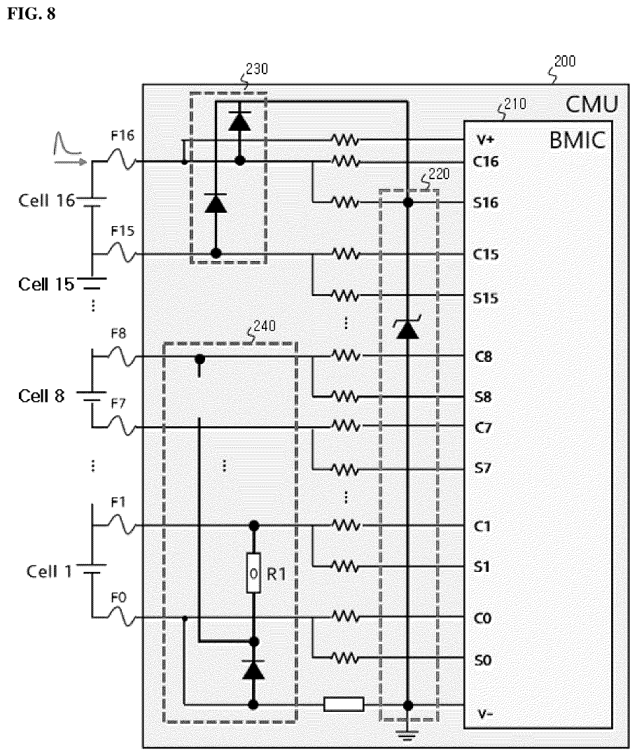

FIG. 8 is a diagram illustrating an adaptive battery cell monitoring device equipped with an EOS protection circuit according to one embodiment of the present disclosure and illustrating a state in which a battery module including 16 battery cells is connected to the adaptive battery cell monitoring device, which is capable of monitoring up to 16 battery cells.

As can be understood from FIG. 8, when the battery module includes 16 battery cells, a resistor (e.g., R1) is mounted at a designated mounting position to connect the next-bottommost fuse F1 among the 17 fuses F0 to F16 to the other end of the third Schottky diode. This allows the EOS protection circuit 220 and the battery cell monitoring device 200 to be adaptively implemented.

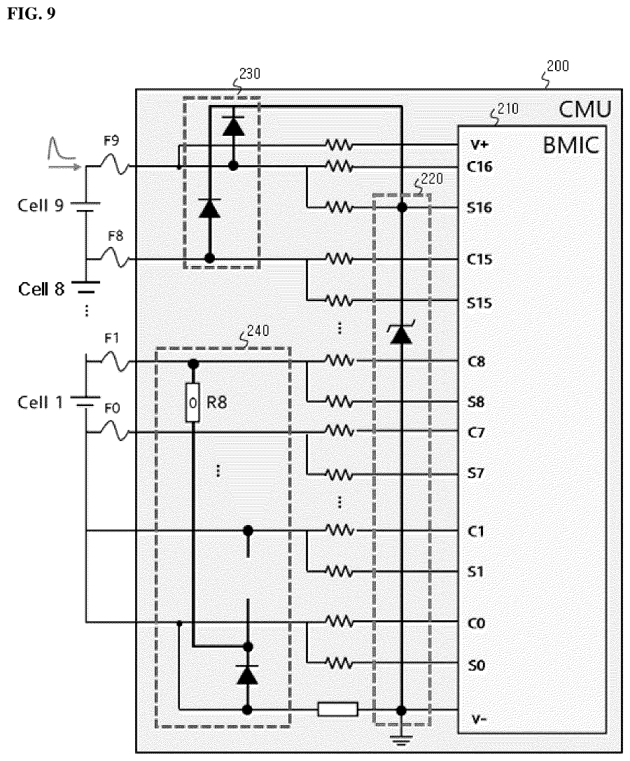

FIG. 9 is a diagram illustrating an adaptive battery cell monitoring device equipped with an EOS protection circuit according to one embodiment of the present disclosure and illustrating a state in which a battery module including 9 battery cells is connected to the adaptive battery cell monitoring device, which is capable of monitoring up to 16 battery cells.

As can be understood from FIG. 9, when the battery module includes 9 battery cells, a resistor (e.g., R8) is mounted at a designated mounting position to connect the next-bottommost fuse F1 among the 10 fuses F0 to F9 to the second end of the third Schottky diode. This allows the EOS protection circuit 220 and the battery cell monitoring device 200 to be adaptively implemented.

The resistor adjustably mounted in the second bypass circuit 240 is intended to connect the circuit at a desired point. Therefore, it is desirable for the resistor to have a low resistance value, such as 1 ohm or less, and more desirably, a resistance value close to 0 ohms.

As used in the present disclosure (including the appended claims), the terms “a ,” “an,” and “the” include both singular and plural references, unless the context clearly states otherwise. Also, it should be understood that any numerical range recited in the present disclosure is intended to include all sub-ranges subsumed therein (unless expressly indicated otherwise) and accordingly, the disclosed numeral ranges include every individual value between the minimum and maximum values of the numeral ranges.

The steps constituting the method according to the present disclosure may be performed in an appropriate order unless a specific order is described unless otherwise specified. In other words, the present disclosure is not necessarily limited to the order in which the steps are recited. All examples described in the present disclosure or the terms indicative thereof (“for example”, “such as”) are merely to describe the present disclosure in detail. Therefore, it should be understood that the scope of the present disclosure is not limited to the embodiments described above or by the use of such terms but defined by the appended claims. Also, it should be apparent to those having ordinary skill in the art that various modifications, combinations, and alternations may be made based on design conditions and factors within the scope of the appended claims or equivalents thereof.

The present disclosure is thus not limited to the embodiments described above and rather intended to include the following appended claims, and all modifications, equivalents, and alternatives falling within the spirit and scope of the following claims.

What is claimed is:

1. An adaptive battery cell monitoring device, comprising:
a cell monitoring circuit configured to monitor n battery cells, where n is a natural number, included in a battery module;
an electrical overstress (EOS) protection circuit configured to protect the cell monitoring circuit from external EOS, the EOS protection circuit being connected between an uppermost terminal of the cell monitoring circuit and a ground terminal of the cell monitoring circuit, wherein the uppermost terminal of the cell monitoring circuit is connected to a positive electrode of an uppermost battery cell of the battery module including k battery cells, where k is a natural number equal to or less than n, and wherein the ground terminal of the cell monitoring circuit is connected to a negative electrode of a bottommost battery cell of the battery module; and
a first bypass circuit configured to bypass the external EOS, wherein the first bypass circuit is connected between a positive electrode of a next-uppermost battery cell of the battery module and the uppermost terminal of the cell monitoring circuit.

2. The adaptive battery cell monitoring device according to claim 1, wherein the first bypass circuit comprises a first diode connected between the positive electrode of the next-uppermost battery cell of the battery module and the uppermost terminal of the cell monitoring circuit.

3. The adaptive battery cell monitoring device according to claim 2, wherein the first bypass circuit further comprises a second diode connected between the positive electrode of the uppermost battery cell of the battery module and the uppermost terminal of the cell monitoring circuit.

4. The adaptive battery cell monitoring device according to claim 1, further comprising:
a second bypass circuit configured to bypass the external EOS, wherein the second bypass circuit is connected between the ground terminal of the cell monitoring circuit and a positive electrode of the bottommost battery cell of the battery module.

5. The adaptive battery cell monitoring device according to claim 4, wherein the second bypass circuit comprises a third diode and a resistor,
wherein a first end of the third diode is connected to the ground terminal of the cell monitoring circuit,
wherein a second end of the third diode is connected to a first end of the resistor, and
wherein a second end of the resistor is connected to the positive electrode of the bottommost battery cell of the battery module.

6. The adaptive battery cell monitoring device according to claim 5, wherein the resistor is detachably provided in the second bypass circuit to allow for position adjustment.

7. The adaptive battery cell monitoring device according to claim 5, wherein the resistor has a resistance value of 1 ohm or less than 1 ohm.

8. The adaptive battery cell monitoring device according to claim 1, wherein the uppermost terminal of the cell monitoring circuit is configured to perform cell balancing for the uppermost battery cell of the battery module.

9. The adaptive battery cell monitoring device according to claim 1, wherein the battery cell monitoring device is a cell monitoring unit (CMU).

10. The adaptive battery cell monitoring device according to claim 1, wherein the battery cell monitoring device is a battery monitoring integrated circuit (BMIC).

11. The adaptive battery cell monitoring device according to claim 1, wherein the EOS protection circuit comprises a transient voltage suppressor (TVS) diode.

12. An adaptive battery cell monitoring device, comprising:
a cell monitoring circuit configured to monitor n battery cells, where n is a natural number, included in a battery module;
an electrical overstress (EOS) protection circuit configured to protect the cell monitoring circuit from external EOS, the EOS protection circuit being connected between an uppermost terminal of the cell monitoring circuit and a ground terminal of the cell monitoring circuit, wherein the uppermost terminal of the cell monitoring circuit is connected to a positive electrode of an uppermost battery cell of the battery module including k battery cells, where k is a natural number equal to or less than n, and wherein the ground terminal of the cell monitoring circuit is connected to a negative electrode of a bottommost battery cell of the battery module; and
a bypass circuit configured to bypass the external EOS, wherein the bypass circuit is connected between the ground terminal of the cell monitoring circuit and a positive electrode of a bottommost battery cell of the battery module.

13. The adaptive battery cell monitoring device according to claim 12, wherein the bypass circuit comprises a diode and a resistor,
wherein a first end of the diode is connected to the ground terminal of the cell monitoring circuit,
wherein a second end of the diode is connected to a first end of the resistor, and
wherein a second end of the resistor is connected to the positive electrode of the bottommost battery cell of the battery module.

14. The adaptive battery cell monitoring device according to claim 13, wherein the resistor is detachably provided in the bypass circuit to allow for position adjustment.

15. The adaptive battery cell monitoring device according to claim 13, wherein the resistor has a resistance value of 1 ohm or less than 1 ohm.

16. The adaptive battery cell monitoring device according to claim 12, wherein the uppermost terminal of the cell monitoring circuit is configured to perform cell balancing for the uppermost battery cell of the battery module.

17. The adaptive battery cell monitoring device according to claim 12, wherein the battery cell monitoring device is a cell monitoring unit (CMU).

18. The adaptive battery cell monitoring device according to claim 12, wherein the battery cell monitoring device is a battery monitoring integrated circuit (BMIC).

19. The adaptive battery cell monitoring device according to claim 12, wherein the EOS protection circuit comprises a transient voltage suppressor (TVS) diode.
